(19) United States
(12) Patent Application Publication
(10) Pub. No.: US 2014/0014816 A1
(43) Pub. Date: Jan. 16, 2014

(54) IMAGING ELEMENT AND IMAGING METHOD

(71) Applicant: Sony Corporation, Tokyo (JP)

(72) Inventor: Takeshi Takeda, Kanagawa (JP)

(21) Appl. No.: 13/927,833

(22) Filed: Jun. 26, 2013

(30) Foreign Application Priority Data
Jul. 13, 2012 (JP) 2012-157071

(51) Int. Cl. H01L 27/148

(52) U.S. Cl. CPC H01L 27/14818
USPC 250/208.1; 257/229

(57) ABSTRACT

There is provided an imaging element including a contact portion that connects first and second regions accumulating a charge to each other, a first transfer portion that is formed between the first region and the contact portion, and a second transfer portion that is formed between the second region and the contact portion.

### BACKGROUND

The present technology relates to an imaging element and an imaging method, and more particularly, to an imaging element and an imaging method capable of suppressing an influence of a dark current.

Since CMOS image sensors according to the related art are generally rolling shutter type image sensors that sequentially read pixels, an image may be distorted due to a difference in an exposure timing. To resolve this problem, a global shutter type of simultaneously reading all of the pixels by providing charge retention portions in the pixels has been suggested (see Japanese Unexamined Patent Application Publication No. 2008-103647). According to the global shutter type, reading is sequentially enabled after all of the pixels are simultaneously read in the charge retention portions. Therefore, since the exposure timing can be set to be common to each pixel, an image can be prevented from being distorted.

### SUMMARY

However, when the charge retention portion and a photoelectric conversion portion are formed over the same substrate, there is a probability that light leaking from the photoelectric conversion portion may invade the charge retention portion. When the light invades the charge retention portion, a false image may occur. Therefore, it is necessary to prevent the light from invading.

To prevent the light from invading, embedding a material shielding light between the charge retention portion and the photoelectric conversion portion can be considered. When such a light shielding material is embedded, the charge retention portion and the photoelectric conversion portion are configured to be connected to each other via a contact and a wiring so that a charge is transmitted.

Japanese Unexamined Patent Application Publication No. 2011-138841 and Japanese Unexamined Patent Application Publication No. 2010-16594 have also suggested image sensors in which a charge retention portion and a photoelectric conversion portion are separately formed. It has been suggested that a charge is transmitted from the photoelectric conversion portion to the charge retention portion via a contact by separately forming the charge retention portion and the photoelectric conversion portion.

When the charge is transmitted via the contact, a dark current may flow from the contact portion. It is difficult to eliminate the dark current. Further, since the dark current also varies due to temperature, the dark current also has a large influence on image quality. Accordingly, deterioration of the image quality caused due to the dark current is preferably prevented.

It is desirable to provide a technology for preventing deterioration of image quality caused due to a dark current.

According to an embodiment of the present disclosure, there is provided an imaging element including a contact portion that connects first and second regions accumulating a charge to each other, a first transfer portion that is formed between the first region and the contact portion, and a second transfer portion that is formed between the second region and the contact portion.

The first region may be a photoelectric conversion portion, and the second region may be a charge retention portion that retains the charge accumulated in the photoelectric conversion portion.

A charge generated by a dark current may be ejected by turning off the first transfer portion and turning on the second transfer portion before the charge accumulated in the first region is transmitted to the second region, and the charge accumulated in the first region may be transmitted to the second region by turning on the first and second transfer portions after the ejection of the charge ends.

A third transfer portion may be connected to the contact portion, and a charge generated by a dark current may be ejected by the third transfer portion during a period other than a period in which the charge accumulated in the first region is transmitted to the second region.

The first and second regions may be formed over different substrates or over different materials.

The first region may be a first charge retention portion that retains at least a part of the charge accumulated in a photoelectric conversion portion, and the second region may be a second charge retention portion that retains the charge from the first charge retention portion.

The first region may be a photoelectric conversion portion, and the second region may be an output portion that outputs a charge accumulated in the photoelectric conversion portion to a signal line.

According to an embodiment of the present disclosure, there is provided an imaging method of an imaging element including a contact portion that connects first and second regions accumulating a charge to each other, a first transfer portion that is formed between the first region and the contact portion, and a second transfer portion that is formed between the second region and the contact portion, the imaging method including ejecting a charge generated by a dark current by turning off the first transfer portion and turning on the second transfer portion before the charge accumulated in the first region is transmitted to the second region, and transmitting the charge accumulated in the first region to the second region by turning on the first and second transfer portions after the ejection of the charge ends.

In the imaging element and the imaging method according to the embodiments of the present technology, the contact portion connects the first and second regions accumulating the charge to each other, the first transfer portion is formed between the first region and the contact portion, and the second transfer portion is formed between the second region and the contact portion. When the charge is transmitted from the first region to the second region, the charge generated by the dark current is ejected under the control of the first and second transfer portions.

According to the embodiments of the present technology, it is possible to prevent image quality from deteriorating due to the dark current.

### BRIEF DESCRIPTION OF THE DRAWINGS

FIG. 1 is a diagram illustrating the configuration of an image sensor;

FIG. 2 is a diagram illustrating the configuration of a unit pixel;

FIG. 3 is a side view illustrating the unit pixel;

FIG. 4 is a circuit diagram illustrating the unit pixel;

FIG. 5 is a diagram illustrating occurrence of a dark current;

FIG. 6 is a diagram illustrating the configuration of a unit pixel according to an embodiment of the present technology;

FIG. 7 is a side view illustrating the unit pixel;

FIG. 8 is a circuit diagram illustrating the unit pixel;

FIG. 9 is a timing chart illustrating an operation of the unit pixel;

FIG. 10 is a circuit diagram illustrating a unit pixel;

FIG. 11 is a timing chart illustrating an operation of the unit pixel;

FIG. 12 is a side view illustrating a unit pixel;

FIG. 13 is a side view illustrating a unit pixel;

FIG. 14 is a circuit diagram illustrating the unit pixel;

FIG. 15 is a side view illustrating a unit pixel;

FIG. 16 is a circuit diagram illustrating the unit pixel;

FIG. 17 is a side view illustrating a unit pixel;

FIG. 18 is a side view illustrating a unit pixel; and

FIG. 19 is a circuit diagram illustrating the unit pixel.

### DETAILED DESCRIPTION OF THE EMBODIMENTS

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, modes (hereinafter referred to as embodiments) for carrying out the present technology will be described. The description will be made in the following order.

1. Configuration of solid-state imaging element

2. Configuration of unit pixel

3. First embodiment of unit pixel

4. Second embodiment of unit pixel

5. Third embodiment of unit pixel

6. Fourth embodiment of unit pixel

7. Fifth embodiment of unit pixel

8. Sixth embodiment of unit pixel

9. Seventh embodiment of unit pixel

10. Advantages

### [Configuration of Solid-State Imaging Element]

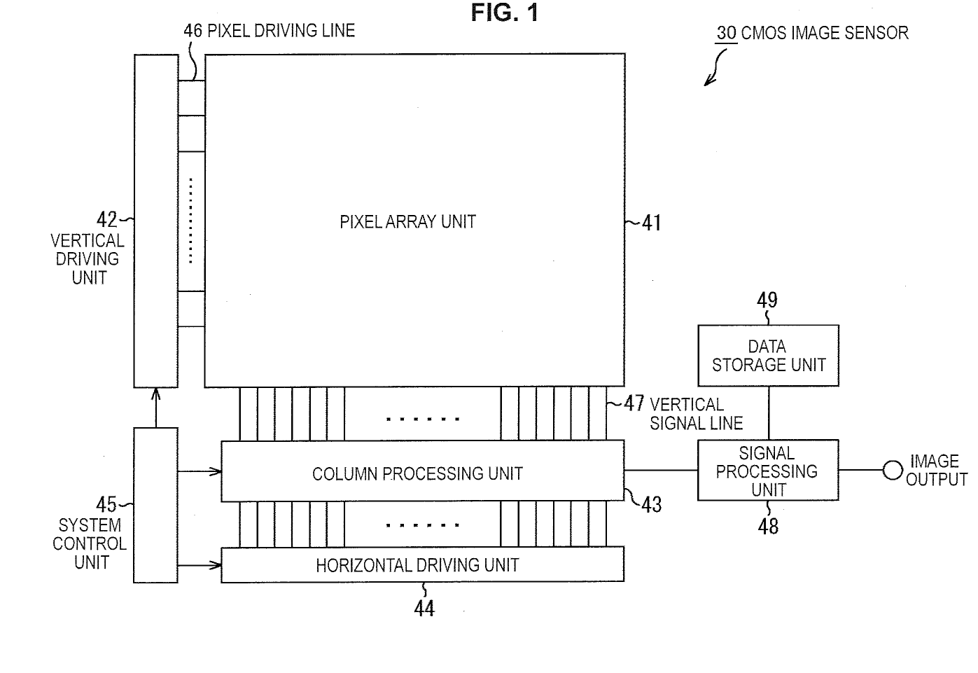

FIG. 1 is a block diagram illustrating an example of the configuration of a complementary metal oxide semiconductor (CMOS) image sensor serving as a solid-state imaging element according to an embodiment of the present technology. A CMOS image sensor 30 includes a pixel array unit 41, a vertical driving unit 42, a column processing unit 43, a horizontal driving unit 44, and a system control unit 45. The pixel array unit 41, the vertical driving unit 42, the column processing unit 43, the horizontal driving unit 44, and the system control unit 45 are formed over a semiconductor substrate (chip) (not illustrated).

In the pixel array unit 41, unit pixels each including a photoelectric conversion element that generates an optical charge of a charge amount corresponding to an amount of incident light and accumulates the optical charge therein are two-dimensionally arrayed in a matrix form. Hereinafter, the optical charge of a charge amount corresponding to an amount of incident light is simply referred to as a “charge” in the following description.

In the pixel array unit 41, a pixel driving line 46 is formed for each row in the pixel array of the matrix form in the right and left directions (the array direction of the pixels of a pixel row) of the drawing and a vertical signal line 47 is formed for each column in the upper and lower directions (the array direction of the pixels of the pixel column) of the drawing. One end of the pixel driving line 46 is connected to an output end corresponding to each row of the vertical driving unit 42.

The CMOS image sensor 30 further includes a signal processing unit 48 and a data storage unit 49. The signal processing unit 48 and the data storage unit 49 may be processed by an external signal processing unit such as a digital signal processor (DSP) installed in a substrate different from the substrate of the CMOS image sensor 30 or software or may be mounted on the same substrate as the CMOS image sensor 30.

The vertical driving unit 42 is a pixel driving unit that includes a shift register or an address decoder, and simultaneously drives all of the pixels of the pixel array unit 41 or drives the pixels in units of rows or the like. Although the specific configuration of the vertical driving unit 42 is not illustrated in the drawing, the vertical driving unit 42 is configured to include a reading scan system, a flushing scan system, or a collective flushing and collective transfer system.

The reading scanning system sequentially selects and scans the unit pixels of the pixel array unit 41 in the units of rows to read signals from the unit pixels. In a case of row driving (rolling shutter operation), in regard to flushing, the reading scan system performs a flushing scan on a reading row to be subjected to a reading scan earlier than a reading scan by a time of a shutter speed. Further, in a case of global exposure (global shutter operation), collective flushing is performed earlier than collective transfer by the time of the shutter speed.

Through the flushing, unnecessary charges are flushed (reset) from the photoelectric conversion elements of the unit pixels of the reading row. Then, a so-called electronic shutter operation is performed through the flushing (reset) of the unnecessary charges. Here, the electronic shutter operation refers to an operation of discarding the optical charge of the photoelectric conversion element and newly starting exposure (starting accumulation of an optical charge).

In first to seventh embodiments to be described below, an operation of also ejecting a charge generated by a dark current is performed. Since a charge generated by the dark current is ejected, an influence of the charge generated by the dark current on image quality or the like can be configured to be reduced.

A signal read through a reading operation performed by the reading scan system is a signal corresponding to an amount of incident light after an immediately previous reading operation or an electronic shutter operation. In the case of the row driving, a period from a reading timing by an immediately previous reading operation or a flushing timing by an electronic shutter operation to a reading timing by the current reading operation is an accumulation period (exposure period) of an optical charge in the unit pixel. In a case of global exposure, a period from collective flushing to collective transfer is an accumulation period (exposure period).

A pixel signal output from each unit pixel of a pixel row selected and scanned by the vertical driving unit 42 is supplied to the column processing unit 43 through each vertical signal line 47. The column processing unit 43 performs predetermined signal processing on the pixel signal output from each unit pixel of the selected row via the vertical signal line 47 for each pixel row of the pixel array unit 41 and temporarily retains the pixel signal subjected to the signal processing.

Specifically, the column processing unit 43 performs at least a noise removing process such as a correlated double sampling (CDS) process as the signal processing. Fixed pattern noise unique to the pixel, such as reset noise or variation in a threshold value of an amplification transistor, is removed through the correlated double sampling performed by the column processing unit 43. Further, the column processing unit 43 may have, for example, an analog-digital (AD) conversion function, as well as the noise removing process, to output a signal level as a digital signal.

The horizontal driving unit 44 includes a shift register or an address decoder and sequentially selects the unit pixels corresponding to the pixel row of the column processing unit 43. The pixel signals subjected to the signal processing by the column processing unit 43 are sequentially output to the signal processing unit 48 through the selection scanning of the horizontal driving unit 44.

The system control unit 45 includes a timing generator that generates various timing signals and controls driving of the vertical driving unit 42, the column processing unit 43, the horizontal driving unit 44, and the like based on the various timing signals generated by the timing generator.

The signal processing unit 48 has at least an addition processing function and performs various kinds of signal processing such as an addition process on the pixel signal output from the column processing unit 43. The data storage unit 49 temporarily stores necessary data of the signal processing in conjunction with the signal processing performed by the signal processing unit 48.

### [Configuration of Unit Pixel]

Next, a specific configuration of a unit pixel 50 arrayed in a matrix form in the pixel array unit 41 in FIG. 1 will be described. Here, to clarify a difference between the unit pixel 50 and a unit pixel to be described below, the configuration of a unit pixel according to the related art will be described first.

In the unit pixel according to the related art, as will be described below, there is a probability that a dark current occurs and image quality may deteriorate due to the influence of the dark current. In unit pixels according to the first to seventh embodiments to be described below, it is possible to prevent the image quality from deteriorating due to the influence of the dark current. To describe the dark current, the configuration of the unit pixel according to the related art will be described first.

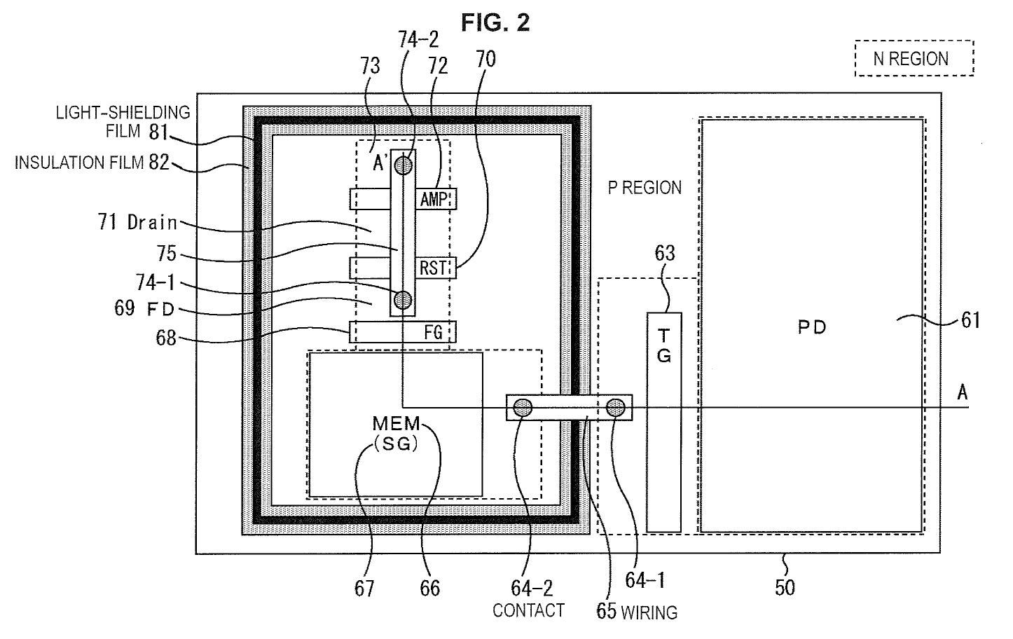

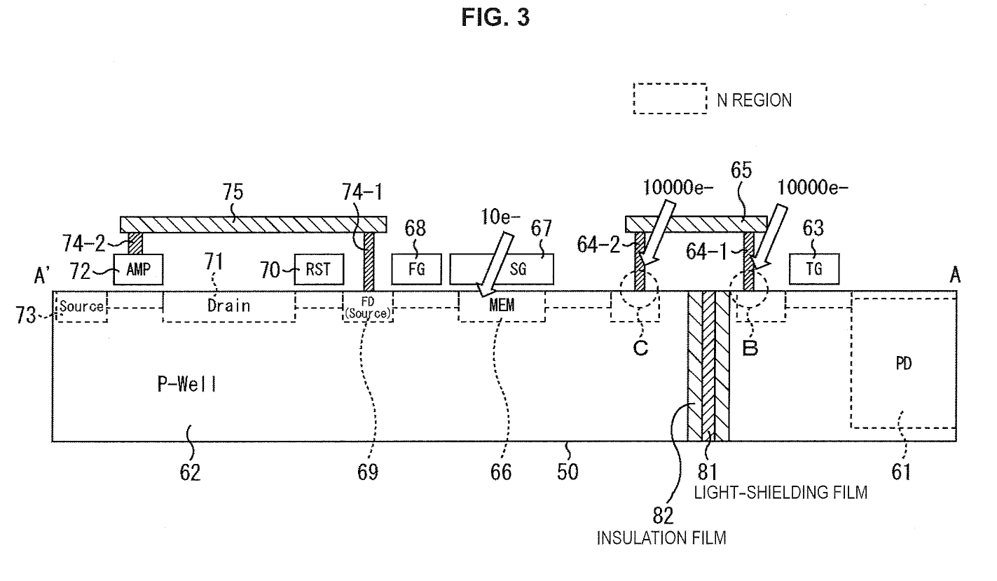

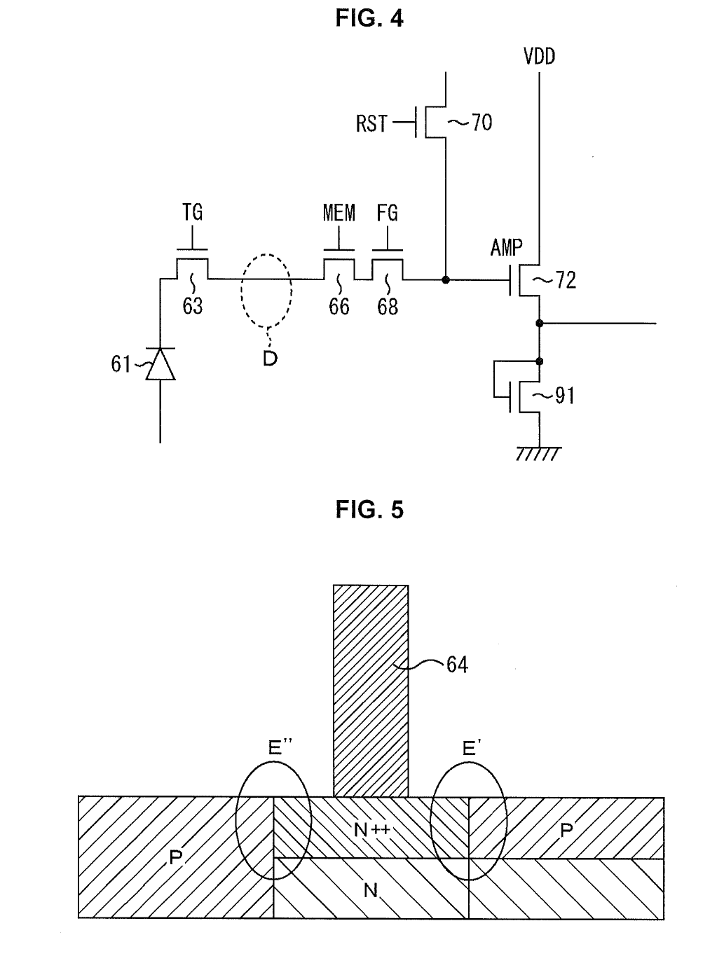

FIGS. 2, 3, and 4 illustrate an example of the configuration of the unit pixel. FIG. 2 is a diagram when the unit pixel is viewed from a light reception surface side. FIG. 3 is a diagram illustrating the unit pixel taken along the A-A′ surface when the light reception surface side of the unit pixel illustrated in FIG. 2 is assumed to be an upper side and the unit pixel is viewed from the side surface. FIG. 4 is a circuit diagram illustrating the circuit of the unit pixel.

The unit pixel 50 includes, for example, a photodiode (PD) 61 as a photoelectric conversion element. The photodiode 61 is, for example, an embedded photodiode formed such that a p-type layer is formed on a substrate surface side with respect to a p-type well layer 62 formed on an n-type substrate and an n-type embedded layer is embedded.

The unit pixel 50 includes not only the photodiode 61 but also a memory portion (MEM) 66 that includes a transfer gate (TG) 63 and a storage gate (SG) 67. The transfer gate 63 transmits a charge photoelectrically converted by the photodiode 61 and accumulated inside the photodiode 61 when a driving signal is applied to a gate electrode.

The memory portion 66 is shielded from light. As illustrated in FIG. 2, a light-shielding film 81 and an insulation film 82 are formed to surround the memory portion 66, and thus the memory portion 66 is shielded from light by the light-shielding film 81. As illustrated in FIGS. 2 and 3, the light-shielding film 81 is formed to be interposed in the insulation film 82.

Thus, since the light-shielding film 81 and the insulation film 82 are formed between the photodiode 61 and the memory portion 66, a charge from the photodiode 61 is transmitted via a contact 64-1, a wiring 65, and a contact 64-2.

In the following description, when a contact is described, the contact includes a wiring in some cases. In the specification, when a charge is transmitted from a photoelectric conversion portion (for example, the photodiode 61) to a charge accumulation portion (for example, the memory portion 66), a passing route of the charge is referred to as a contact. The description will continue on the assumption that the contact includes, for example, the contact 64-1, the wiring 65, and the contact 64-2.

The unit pixel 50 includes a floating gate 68 and a floating diffusion (FD) region 69. The floating gate 68 transmits the charge accumulated in the memory portion 66 to the floating diffusion region 69 when a driving signal is applied to the gate electrode of the floating gate 68. The floating diffusion region 69 is a charge voltage conversion unit formed of an n-type layer and converts the charge transmitted from the memory portion 66 by the floating gate 68 into a voltage.

The unit pixel 50 further includes a reset gate (RST) 70 and an amplification transistor (AMP: amplifier) 72. The reset gate 70 is connected between a power source and the floating diffusion region 69, and thus resets the floating diffusion region 69 when a driving signal is applied to the gate electrode.

The drain electrode and the gate electrode of the amplification transistor 72 are connected to the power source and the floating diffusion region 69, respectively, and thus the amplification transistor 72 reads the voltage of the floating diffusion region 69. The floating diffusion region 69 and the amplification transistor 72 are connected to each other via a contact 74-1, a wiring 75, and a contact 74-2.

Although not illustrated in the drawings, the unit pixel 50 further includes a selection transistor. For example, the drain electrode and the source electrode of the selection transistor are connected to the source electrode of the amplification transistor 72 and the vertical signal line 47 (see FIG. 1), respectively, and thus the selection transistor selects the unit pixel 50 from which a pixel signal is to be read when a driving signal is applied to the gate electrode. The selection transistor may be configured to be connected between the power source and the drain electrode of the amplification transistor 72.

The CMOS image sensor 30 (see FIG. 1) having the above-described configuration realizes the global shutter operation (global exposure) by simultaneously starting to expose all of the pixels, simultaneously stopping exposing all of the pixels, and transmitting the charges accumulated in the photodiodes 61 to the memory portion 66 shielded from light. Through this global shutter operation, an image with no distortion can be captured during an exposure period identical in all of the pixels.

As illustrated in FIGS. 2 and 3, there is a probability that the influence of a dark current may be received when the charge is transmitted from the photodiode 61 to the memory portion 66 via the contact 64-1, the wiring 65, and the contact 64-2. Referring to FIG. 3, a portion in which the photodiode 61 comes into contact with the contact 64-1 is referred to as a portion B (in FIG. 3, a portion indicated by a dotted circle) and a portion in which the memory portion 66 comes into contact with the contact 64-2 is referred to as a portion C (In FIG. 3, a portion indicated by a dotted circle). There is a probability that a dark current may occur in the portions B and C and may be transmitted.

FIG. 5 is an enlarged diagram illustrating a portion of the contact 64. The dark current is a current which is generated from a depletion layer E′ (depletion layer E″) of a PN junction between an N-type diffusion layer below the contact 64 and the p-type well layer 62 in the periphery of the N-type diffusion layer. Accordingly, as long as the PN junction is present, it is difficult to eliminate occurrence of the dark current on principle.

The higher a carrier concentration of the N-type diffusion layer is, the lower a resistance between the contact and a Si (silicon) substrate is. Therefore, in general, the concentration of the N-type diffusion layer below the contact 64 is set such that the carrier concentration is equal to or greater than 10E19/cm³. Thus, the carrier concentration is set to be higher than that of the other N region. Therefore, the dark current depends on the size of the contact 64 or the diffusion region. However, in general, a dark current of about 10000 electrons/sec occurs from one contact in a case of a CMOCS design rule of the 90 nm generation (see FIG. 3).

To suppress the dark current from the PN junction even slightly, lowering the carrier concentration somewhat and weakening the electric field of the PN junction can be considered. However, it is difficult to completely eliminate the dark current. Since the amount of dark current occurring from the PN junction is changed depending on temperature, it is necessary to consider the influence of the change in the amount of the dark current depending on temperature as well. Accordingly, although the carrier concentration is lowered, it is difficult to reduce the influence of the dark current.

As illustrated in FIG. 3, for example, the charge of the dark current occurring in the portion B is transmitted to the portion C via the contact 64-1, the wiring 65, and the contact 64-2. As a result, the charge may be accumulated in the memory portion 55. Referring also to FIG. 4, the contact 64-1, the wiring 65, and the contact 64-2 are located in a portion D indicated by a dotted line in FIG. 4 between the transfer gate 63 and the memory portion 66. Therefore, it can be understood that the dark current easily flows from the transfer gate 63 to the memory portion 66.

For example, it can be understood that when the dark current of about 10000 electrons/sec is transmitted to the memory portion 66, as illustrated in FIG. 3, the influence of the dark current is large compared to an accumulation amount of the memory portion 66. Since cases in which an accumulation time is a relatively long time such as 1 second do not occur often, the dark current of about 10000 electrons/sec is not considered to be transmitted often in practice. However, even when the accumulation time is short, the dark current occurs, the charge generated by the dark current is transmitted, and thus the dark current has an influence on the amount of charge accumulated in the memory portion 66. Image quality may deteriorate due to this influence.

### [First Embodiment of Unit Pixel]

Thus, the unit pixel configured to reduce the influence of the dark current will be described below. The unit pixel to be described below performs control by disposing gates in front of and behind a PN junction in which a dark current occurs to control ON and OFF timings of the two gates so that the occurring dark current is not mixed with a photoelectrically converted charge.

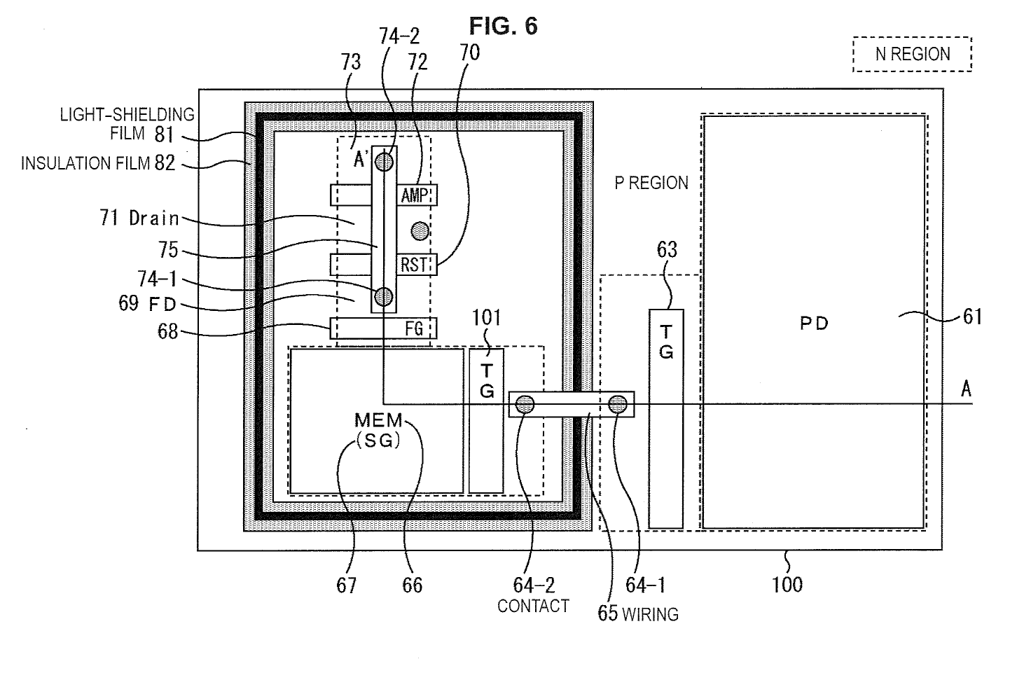

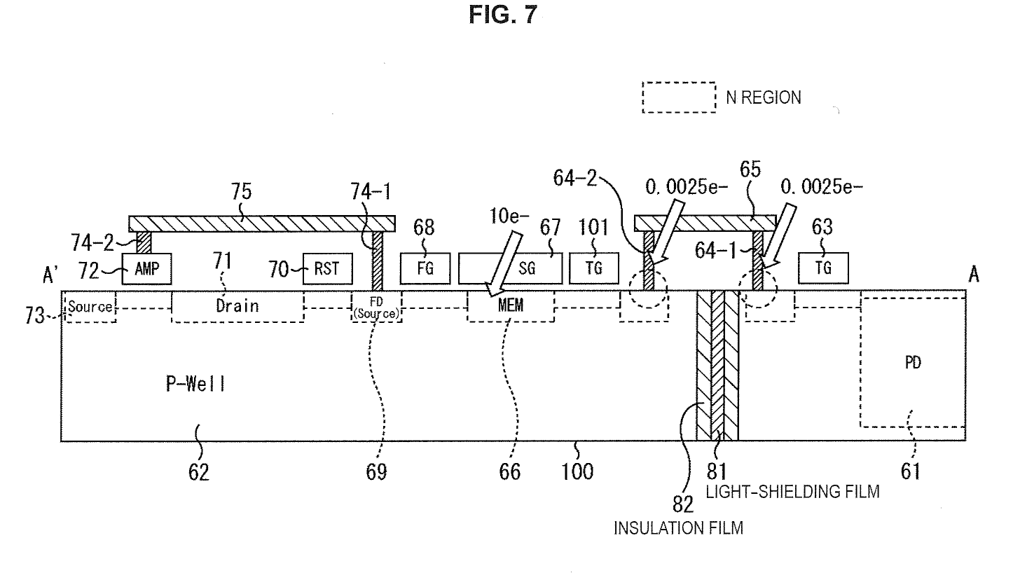

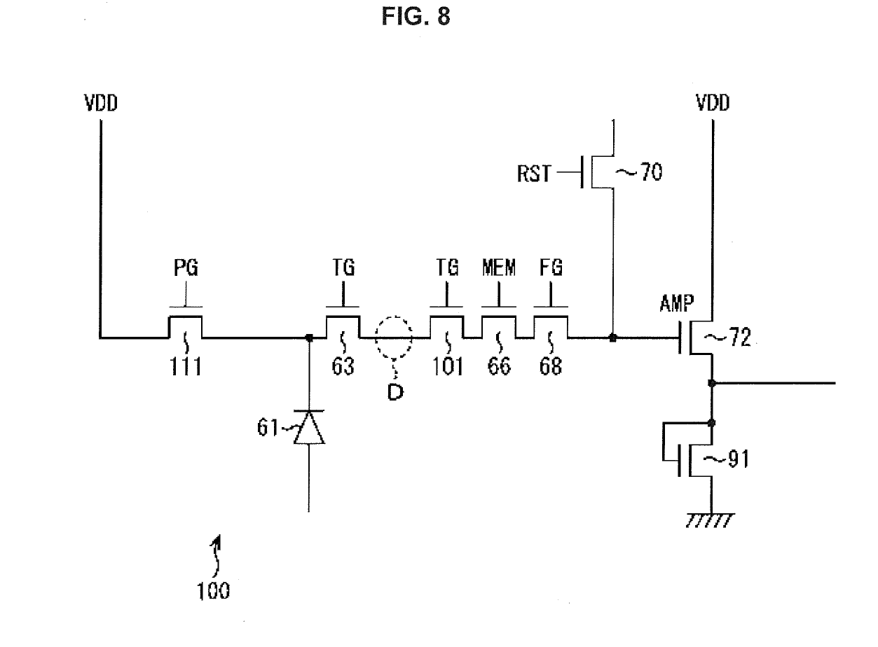

FIGS. 6, 7, and 8 illustrate an example of the configuration of a unit pixel 100 capable of reducing the influence of the dark current. FIG. 6 is a diagram when the unit pixel 100 is viewed from the light reception surface side. FIG. 7 is a diagram illustrating the unit pixel 100 taken along the A-A′ surface when viewed from the side surface on the assumption that the light reception surface side of the unit pixel 100 illustrated in FIG. 6 is an upper side. FIG. 8 is a circuit diagram illustrating the unit pixel 100.

FIGS. 6, 7, and 8 correspond to FIGS. 2, 3, 4, respectively. The reference numerals are given to constituent elements having the same functions and the description thereof will be omitted. In the following description, the reference numerals are also given to constituent elements having the same functions in FIGS. 2 to 8 and the description thereof will be omitted.

The unit pixel 100 illustrated in FIGS. 6 to 8 is configured such that a transfer gate 101 is added to the unit pixel 50 illustrated in FIGS. 2 to 4. The transfer gate 101 is formed between a contact 64-2 and a memory portion 66. That is, the unit pixel 100 illustrated in FIGS. 6 to 8 includes a transfer gate 63 formed between a photodiode 61 and a contact 64-1 and the transfer gate 101 formed between the memory portion 66 and the contact 64-2.

As illustrated in FIG. 8, the unit pixel 100 includes a photo gate (PG) 111. The photo gate 111 is formed to reset the photodiode.

Thus, the photodiode 61 and the memory portion 66 are formed via the contact 64-1, a wiring 65, and the contact 64-2 over the same substrate, and the transfer gate 63 and the transfer gate 101 are formed in front of and behind the contact 64-1, the wiring 65, and the contact 64-2.

In the first embodiment and second to seventh embodiments to be described below, likewise, a region, such as the photodiode 61 or the memory portion 66, which temporarily accumulates a charge, is connected via a contact, and gates (transfer portion) that control transfer of the charge are configured to be formed in front of and behind the contact.

In this configuration, by turning on the photo gates 111, all of the pixels are simultaneously reset using the photo gates 111, and then the charges are accumulated in the photodiodes 61. Immediately before the charge is transmitted to the memory portion 66, the transfer gate 63 is set to enter an OFF state and the transfer gate 101 is set to enter an ON state, and thus the dark current occurring in the memory portion 66 or the contact 64 is ejected to a drain 71. After the dark current is ejected, the transfer gate 63 is set to enter the ON state and the charge is transmitted from the photodiode 61 to the memory portion 66.

By performing this process, it is possible to transmit the charge to a retention portion (memory portion 66) without mixture of a signal charge with the charge generated in a diffusion layer of the contact 64. When the transfer gate 63 and the transfer gate 101 are sequentially turned off after the transfer, the charge is not mixed with the signal charge even when a dark current subsequently occurs in the contact portion until reading.

By achieving this configuration and the process, as illustrated in FIG. 7, it is possible to considerably reduce an amount of charge generated by the transmitted dark current. Referring to FIG. 7, a time in which the dark current is mixed with the signal charge is a time in which the transfer gate 63 and the transfer gate 101 are turned on together, that is, a time in which the charge is transmitted from the photodiode 61 to the memory portion 66. A time in which the two gates are turned on is a short time such as 250 ns, and the charge occurring meanwhile by dark current is about the maximum 0.0025 electrons.

Accordingly, it is possible to prevent the charge generated by the dark current from being mixed with the signal charge. Even when the charge generated by the dark current is mixed with the signal charge, the amount of charge is very small, thereby not causing deterioration of the image quality.

### [Driving Example of Unit Pixel]

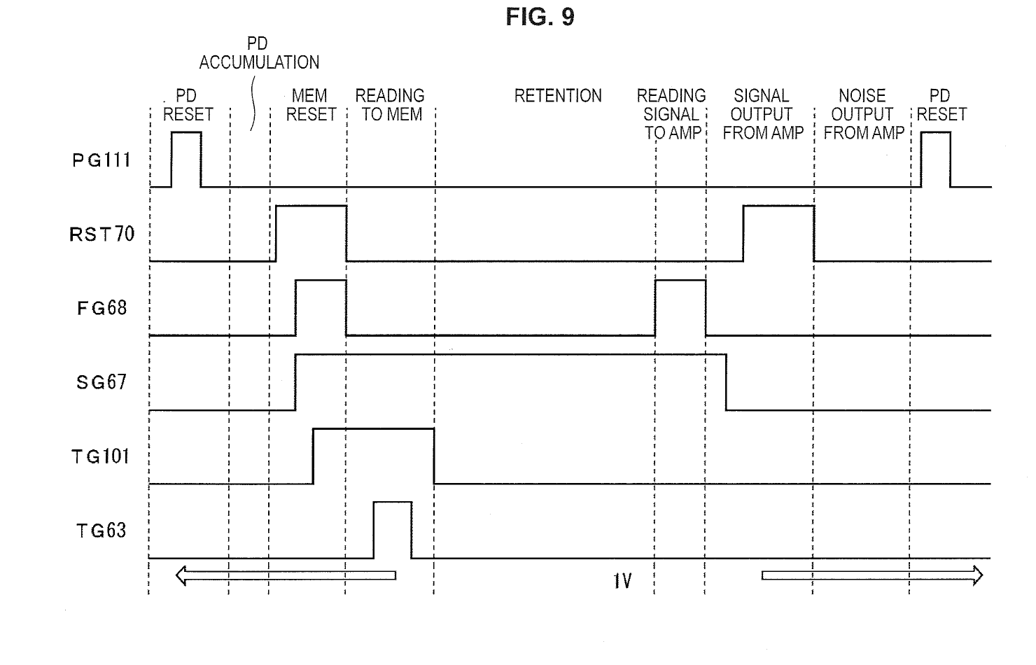

Hereinafter, a driving example of the unit pixel 100 in the CMOS image sensor 30 realizing the global shutter operation will be described with reference to a timing chart of FIG. 9. In FIG. 9, for example, the charge accumulation time of the photo gate 111 is short, as illustrated in the drawing. However, the charge accumulation time is illustrated so as to be short to facilitate the description and actual time intervals are not accurately illustrated.

First, when a driving signal to the photo gate 111 is turned on, the photodiode 61 is reset. The reset is performed on all of the pixels. After the reset ends, the photo gates 111 are turned off and charges newly acquired from light from a subject are accumulated in the photodiodes 61 in all of the pixels en bloc.

The charges accumulated in the photodiodes 61 are transmitted to the memory portion 66 in all of the pixels en bloc. Before the charge is transmitted to the memory portion 66, the memory portion 66 is reset. In the resetting of the memory portion 66, the charge accumulated in the memory portion 66 and the floating diffusion region 69 is initialized (reset) by turning on each driving signal of the reset gate 70, the floating gate 68, and the storage gate 67.

When the memory portion 66 is reset, a driving signal to the transfer gate 101 is also turned on. By turning on the transfer gate 101, the charge generated by the dark current in the portion of the contact 64 is ejected together with the resetting of the memory portion 66. In other words, when the transfer gate 101 is turned on, the memory portion 66 is reset and the charge generated by the dark current is also reset.

When the memory portion 66 and the charge generated by the dark current are reset, the transfer of the charge from the photodiode 61 to the memory portion 66 starts. When the charge is transmitted, the driving signals of the reset gate 70 and the floating gate 68 are turned off. The driving signals of the storage gate 67 and the transfer gate 101 are maintained to be turned on. When the driving signal to the transfer gate 63 is turned on in this state, the charge is transmitted from the photodiode 61 to the memory portion 66 via the contact 64-1, the wiring 65, and the contact 64-2.

After the transfer, the charge accumulated in the memory portion 66 is retained. During the retention of the charge, only the driving signal to the storage gate 67 is turned on. In the case of the global shutter, the retention time is different in each pixel. At a reading timing, the driving signal to the floating gate 68 is turned on and output to the amplification transistor 72 is performed. When a signal is output from the amplification transistor 72 to the vertical signal line 47 (see FIG. 1), the turned-on driving signals of the floating gate 68 and the storage gate 67 are switched to be turned off and the driving signal of the reset gate 70 is switched to be turned on.

Thus, when the signal is output from the amplification transistor 72, all of the driving signals are set to be turned off and noise is output from the amplification transistor 72. Then, by turning on the driving signal of the photo gate 111, the photodiode 61 is reset. By repeatedly performing this process on each unit pixel 100, the output of data corresponding to one pixel is repeated.

### [Second Embodiment of Unit Pixel]

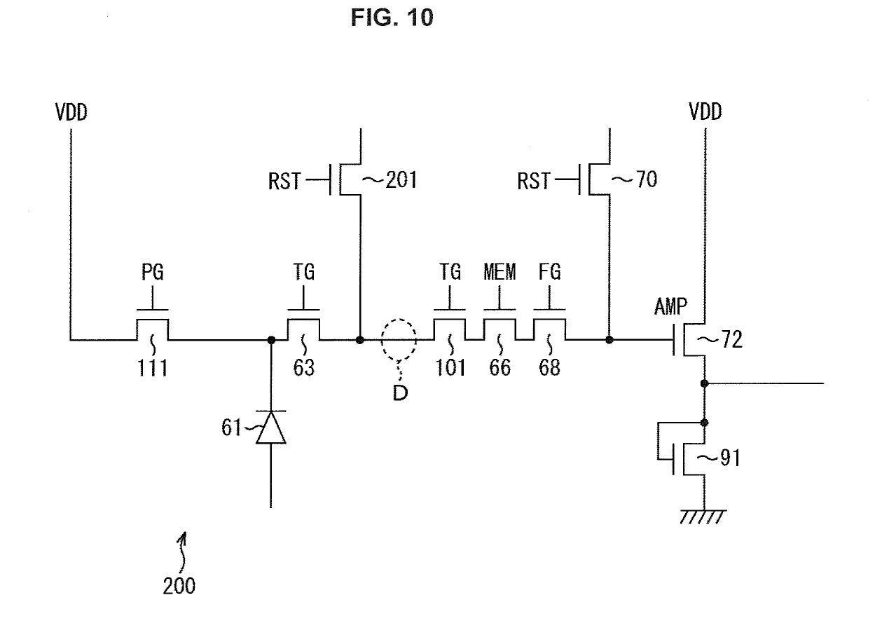

Next, the configuration of a unit pixel according to a second embodiment will be described. FIG. 10 is a circuit diagram illustrating a unit pixel 200 according to the second embodiment. When the unit pixel 100 illustrated in FIG. 8 according to the first embodiment is compared to the unit pixel 200 illustrated in FIG. 10 according to the second embodiment, the unit pixel 200 is different from the unit pixel 100 in that a reset gate 201 is added and the remaining configuration is the same.

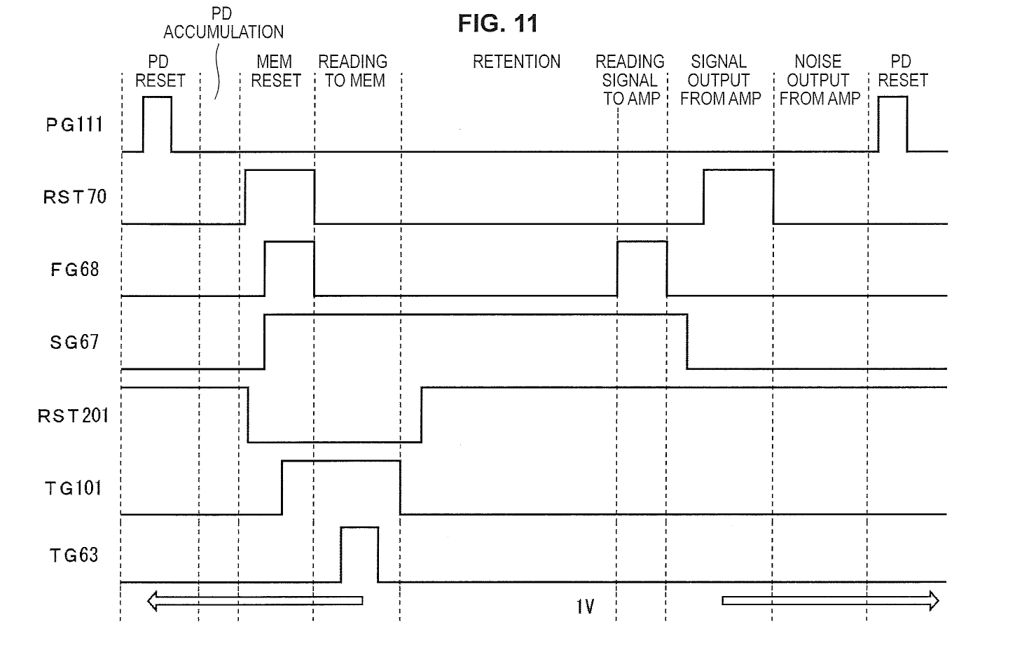

The reset gate 201 is formed between a transfer gate 63 and a transfer gate 101. In other words, the reset gate 201 is formed in a portion in which a contact 64 and a wiring 65 are present. For example, the reset gate 201 is branched from the wiring 65 to be formed. The reset gate 201 is formed to eject a dark current occurring in the portion of the contact 64. The ejection of the dark current will be described with reference to the timing chart of FIG. 11.

The timing chart illustrated in FIG. 11 is a chart in which a timing chart of the reset gate 201 is added to the timing chart illustrated in FIG. 9. A driving signal of the reset gate 201 is set as a signal that is turned off during a period other than the period in which the memory portion 66 is reset and the period in which the charge is transmitted from a photodiode 61 to a memory portion 66 after the resetting of the memory portion 66.

Thus, since the dark current occurring in the portion of the contact 64 is normally ejected by the reset gate 201 during a time other than a time of the transfer of the charge from the photodiode 61 to the memory portion 66, it is possible to reduce the influence of the dark current. Accordingly, even when a large amount of dark current occurs during the retention of the charge, the charge is entirely ejected via the reset gate 201, thereby also preventing leakage of the charge to the memory portion 66.

### [Third Embodiment of Unit Pixel]

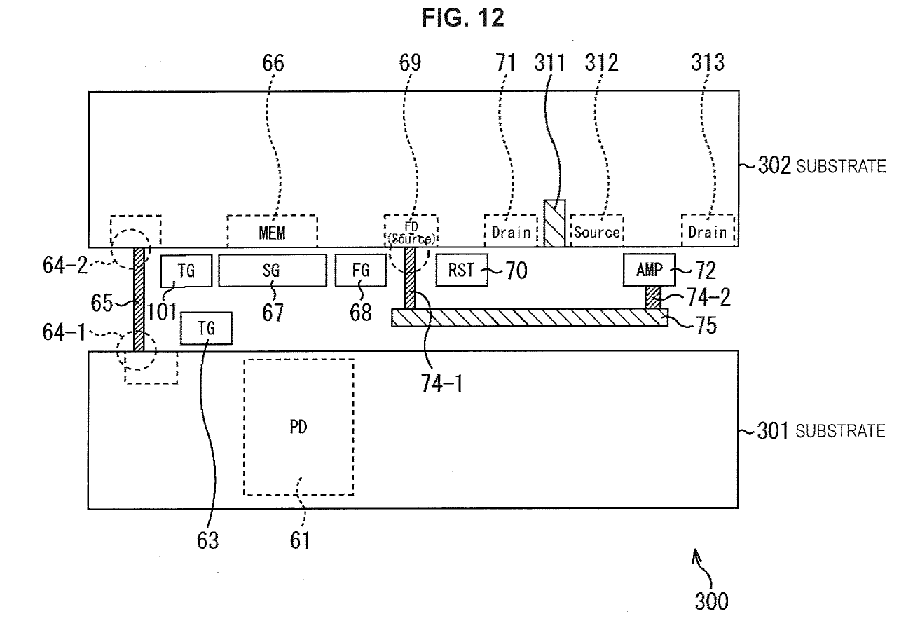

Next, the configuration of a unit pixel according to a third embodiment will be described. FIG. 12 is a side view illustrating a unit pixel 300 according to the third embodiment. When the unit pixel 100 illustrated in FIG. 7 according to the first embodiment is compared to the unit pixel 300 illustrated in FIG. 12 according to the third embodiment, the unit pixel 300 is different from the unit pixel 100 in that the unit pixel 300 is formed from two substrates 301 and 302.

A photodiode 61 and a transfer gate 63 are formed in the substrate 301. A transfer gate 101, a memory portion 66, a storage gate 67, a floating gate 68, a floating diffusion region 69, a reset gate 70, a drain 71, an amplification transistor 72, an insulation layer 311, a source 312, and a drain 313 are formed in the substrate 302. The substrates 301 and 302 are connected to each other via a contact 64-1, a wiring 65, and a contact 64-2.

The unit pixel 300 illustrated in FIG. 12 are formed from the substrates 301 and 302. The substrate 301 serves as a photoelectric conversion substrate and the substrate 302 serves as an accumulation substrate. Thus, the photoelectric conversion substrate and the accumulation substrate can be separately provided to be disposed on upper and lower sides, the substrates can be connected to each other by the contacts 64 and the wiring 65, and the transfer gate 63 and the transfer gate 101 can be configured with the contacts 64 and the wiring 65 interposed therebetween.

Here, two different substrates have been described. However, different material regions may be formed over one substrate and a photoelectric conversion portion and an accumulation portion are formed over the different materials. In the fourth to seventh embodiments to be described below, a case of different substrates will be exemplified, but a photoelectric conversion portion and an accumulation portion may be formed on different material.

When such a configuration is realized, the unit pixel operates based on the timing chart illustrated in FIG. 9, as in the unit pixel 50 according to the first embodiment. Since the transfer gate 63 and the transfer gate 101 are formed before and after the wiring 65, the process can be performed without mixture of the signal charge with the dark current occurring in the portion of the contact 64, as in the unit pixel 50 according to the first embodiment.

### [Fourth Embodiment of Unit Pixel]

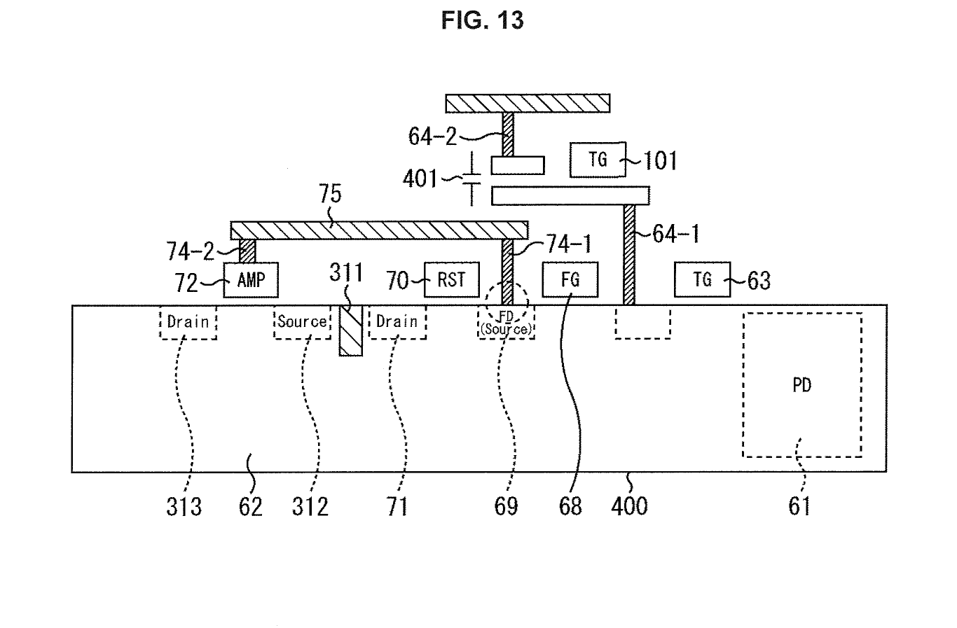

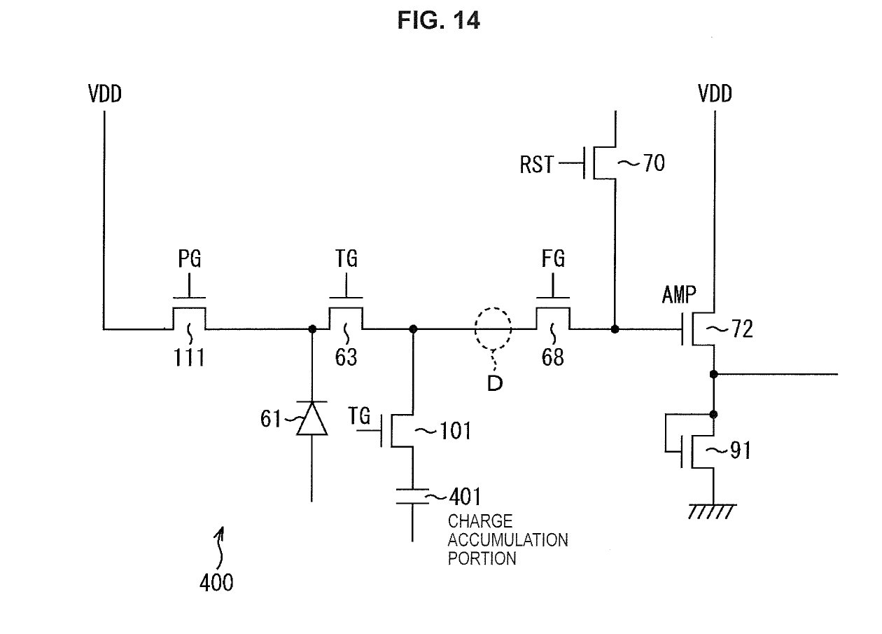

Next, the configuration of a unit pixel according to a fourth embodiment will be described. FIG. 13 is a side view illustrating a unit pixel 400 according to the fourth embodiment. FIG. 14 is a circuit diagram illustrating the unit pixel 400 according to the fourth embodiment. When the unit pixel 100 illustrated in FIG. 7 according to the first embodiment is compared to the unit pixel 400 illustrated in FIG. 13 according to the fourth embodiment, the unit pixel 400 is different from the unit pixel 100 in that the unit pixel 400 includes a charge accumulation portion (capacitor) 401.

The charge accumulation portion 401 is formed as a charge retention portion and is formed instead of the memory portion 66. The charge accumulation portion 401 includes a polycrystalline silicon (PolySi) electrode. A transfer gate 63 is formed on the side of the photodiode 61 of the contact 64-1 and a transfer gate 101 is formed on the side of the charge accumulation portion 401.

Thus, even in the unit pixel 400 illustrated in FIG. 13, the transfer gates 63 and 101 are formed in front of and behind the contact 64-1 connected to the charge accumulation portion 401. The unit pixel 400 performs a process based on the timing chart illustrated in FIG. 9. That is, before transfer of a charge starts, the charge generated by the dark current is ejected by turning on the transfer gate 101 and turning off the transfer gate 63. Then, the charge is transmitted from the photodiode 61 to the charge accumulation portion 401 by turning on the transfer gates 101 and 63.

By transmitting the charge in this way, it is possible to prevent the signal charge from being mixed with the charge generated by the dark current even in the unit pixel 400, as in the unit pixel 100 according to the first embodiment or the unit pixel 300 according to the third embodiment, as described above.

### [Fifth Embodiment of Unit Pixel]

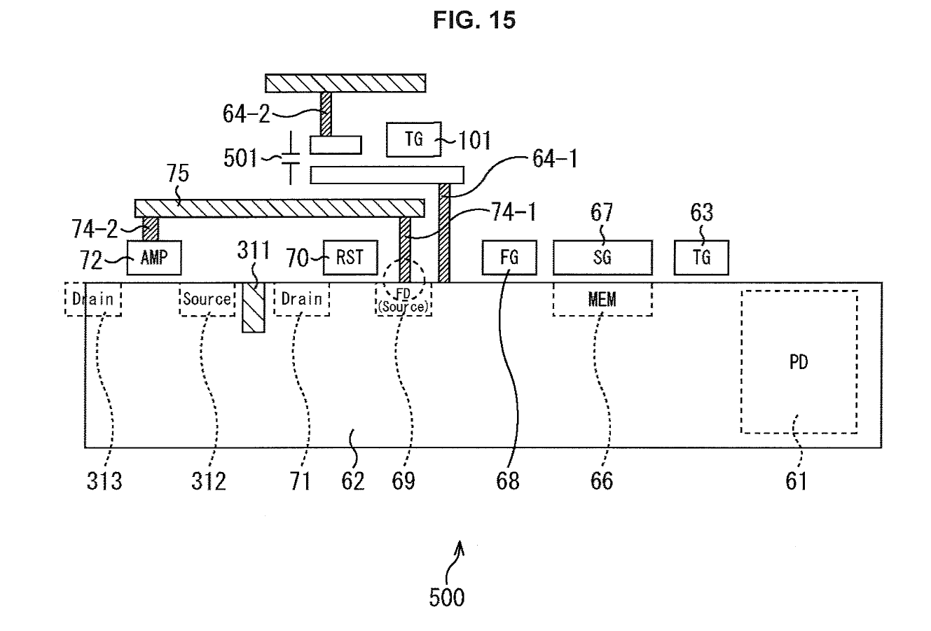

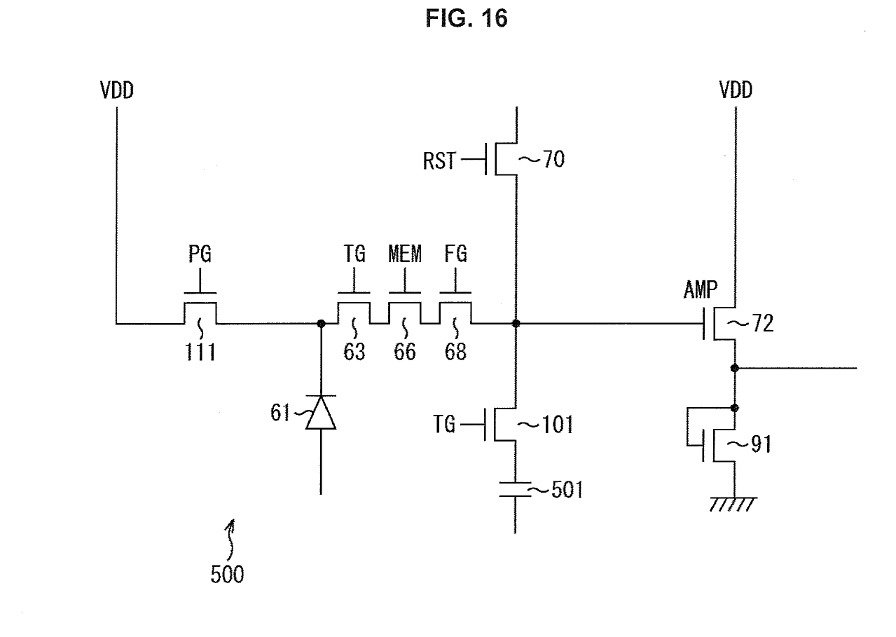

Next, the configuration of a unit pixel according to a fifth embodiment will be described. FIG. 15 is a side view illustrating a unit pixel 500 according to the fifth embodiment. FIG. 16 is a circuit diagram illustrating the unit pixel 500 according to the fifth embodiment.

When the unit pixel 400 illustrated in FIG. 13 according to the fourth embodiment is compared to the unit pixel 500 illustrated in FIG. 15 according to the fifth embodiment, the unit pixel 500 is different from the unit pixel 400 in that the unit pixel 500 includes not only a charge accumulation portion (capacitor) 501 but also a memory portion 66. When the unit pixel 500 is compared to the unit pixel 100 illustrated in FIG. 7 according to the first embodiment, the unit pixel 500 is different from the unit pixel 400 in that the unit pixel 500 includes a charge accumulation portion 501. That is, the unit pixel 500 includes two accumulation portions that accumulate a charge.

As in the unit pixel 400 illustrated in FIG. 13, the unit pixel 500 illustrated in FIG. 15 includes the charge accumulation portion 501 that serves as a charge retention portion including a polycrystalline silicon (PolySi) electrode and the memory portion 66 that serves as a charge retention portion embedded in a p-type well layer 62.

A contact 64-1 connected to the charge accumulation portion 501 is formed between a floating gate 68 and a reset gate 70. The floating gate 68 is formed on one side of the contact 64-1 and the transfer gate 101 is formed on the side of the charge accumulation portion 501 of the other side.

In the unit pixel 500, a charge from the photodiode 61 is transmitted to the memory portion 66. For example, when a charge equal to or greater than the capacity of the memory portion 66 is transmitted, the charge is transmitted and accumulated in the charge accumulation portion 501. At this time, two gates, the floating gate 68 and the transfer gate 101, are formed in front of and behind the contact 64-1. Therefore, as in the above-described embodiments, since the charge generated by the dark current occurring in the portion of the contact 64-1 can be ejected by switching ON and OFF of the two gates, it is possible to prevent the signal charge from being mixed with the charge generated by the dark current.

The reset gate 70 can be used to eject the dark current occurring in the portion of the contact 64-1. For example, as in the unit pixel 200 according to the second embodiment, the reset gate 70 can be set to enter the state in which the dark current is ejected by turning on the driving signal during a time other than the time of the transfer of the charge to the memory portion 66 or the charge accumulation portion 501, as described with reference to the timing chart of FIG. 11. Thus, as described in the second embodiment, it is possible to reduce the influence of the dark current.

Since the unit pixel 500 illustrated in FIGS. 15 and 16 includes not only the charge accumulation portion 501 but also the memory portion 66, a charge can be configured to be retained only in the memory portion 66 which is an embedded channel portion at the time of a small signal. Thus, it is possible to improve implication characteristics at the time of a small signal.

### [Sixth Embodiment of Unit Pixel]

Next, the configuration of a unit pixel according to a sixth embodiment will be described. The sixth embodiment is an embodiment applicable also to a device other than the global shutter. In the sixth embodiment, for example, a photoelectric conversion portion is formed of a separate material such as an organic semiconductor rather than Si (p-type well layer 62).

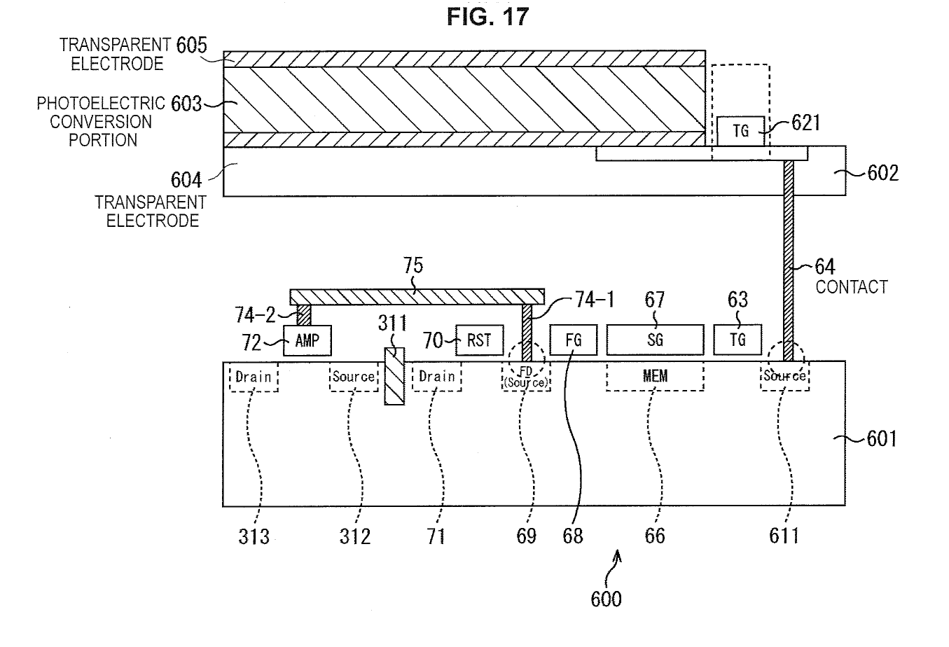

FIG. 17 is a side view illustrating a unit pixel 600 according to the sixth embodiment. The unit pixel 600 illustrated in FIG. 17 according to the sixth embodiment is formed from two substrates, a photoelectric conversion substrate and an accumulation substrate, as in the unit pixel 300 illustrated in FIG. 12 according to the third embodiment.

A substrate 601 serves as the accumulation substrate. A transfer gate 63, a memory portion 66, a storage gate 67, a floating gate 68, a floating diffusion region 69, a reset gate 70, a drain 71, an amplification transistor 72, an insulation layer 311, a source 312, a drain 313, and a source 611 are formed in the substrate 601. The photoelectric conversion substrate includes a substrate 602, a photoelectric conversion portion 603, and transparent electrodes 604 and 605.

The substrate 602 is formed of polycrystalline silicon (PolySi) and a transfer gate 621 including a thin film transistor (TFT) is formed in a part of the substrate 602. The transfer gate 621 may include a portion other than the TFT. The photoelectric conversion portion 603 is formed over the substrate 602 so as to be interposed between the transparent electrodes 604 and 605. The photoelectric conversion portion 603 corresponds to, for example, the photodiode 61 of the unit pixel 100 illustrated in FIG. 7, and converts light from a subject into a charge and accumulates the charge.

The charge from the photoelectric conversion portion 603 is transmitted to the memory portion 66 via the contact 64. Since the charge is transmitted under the control of the transfer gates 621 and 63, the charge is transmitted without mixture of the signal charge with the charge generated by the dark current occurring from the contact 64, as in the unit pixel 100 according to the first embodiment.

### [Seventh Embodiment of Unit Pixel]

Next, the configuration of a unit pixel according to a seventh embodiment will be described. The seventh embodiment is an embodiment applicable also to a device other than the global shutter. In the first to sixth embodiments, the configurations in which the charge accumulation portion such as the memory portion 66 or the charge accumulation portion 401 is provided and the charge is transmitted from the photodiode 61 or the photoelectric conversion portion 603 and is accumulated once have been exemplified. In the seventh embodiment, a unit pixel including no charge accumulation portion will be exemplified.

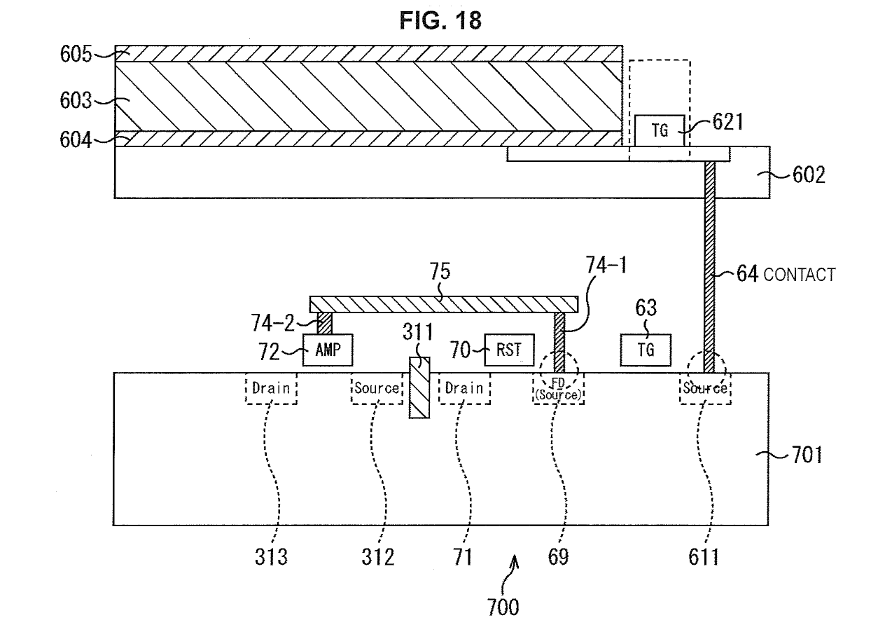

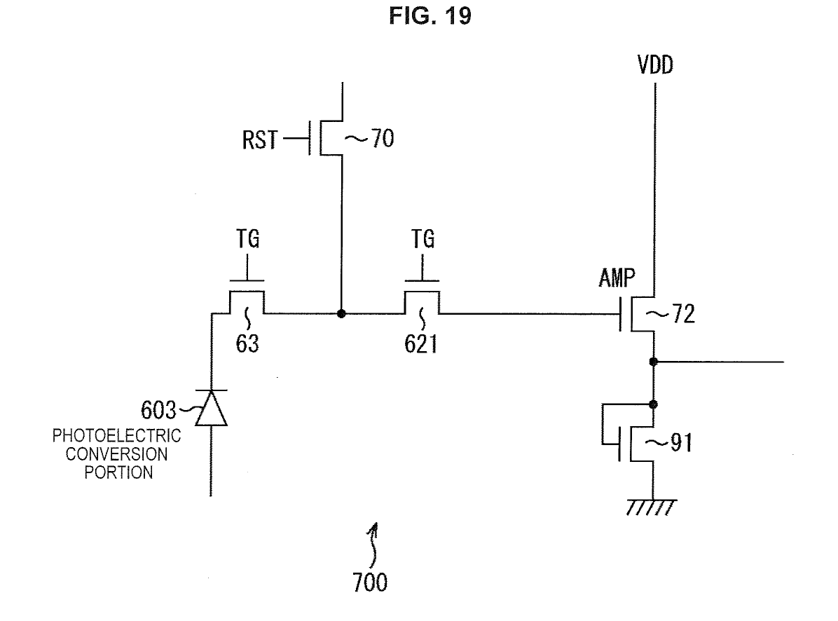

A unit pixel 700 illustrated in FIG. 18 according to the seventh embodiment includes a photoelectric conversion substrate, as in the unit pixel 600 illustrated in FIG. 17. In the photoelectric conversion substrate, a photoelectric conversion portion 603 is formed over a substrate 602 so as to be interposed between transparent electrodes 604 and 605.

In the unit pixel 700, the photoelectric conversion portion 603 retains a charge and the retained charge is output to a vertical signal line 47 (see FIG. 1) via a substrate 701. The substrate 701 has a configuration in which the charge is transmitted (output) from the photoelectric conversion portion 603 to the signal line. Specifically, the substrate 701 includes a transfer gate 63, a floating diffusion region 69, a reset gate 70, a drain 71, an amplification transistor 72, an insulation layer 311, a source 312, a drain 313, and a source 611.

Even in the unit pixel 700 having such a configuration, since the charge retained by the photoelectric conversion portion 603 is transmitted to the vertical signal line 47 via the substrate 701, the charge is transmitted under the control of the transfer gate 621 and the transfer gate 63. Therefore, as in the unit pixel 100, the transfer can be realized without mixture of the signal charge with the charge generated by the dark current occurring from the contact 64.

### [Advantages]

Thus, the charge generated by the dark current is ejected by providing the gates in front of and behind the contact in which there is a probability of the dark current occurring and turning on one of the gates when the charge is transmitted. After the ejection of the dark current ends, the signal charge is transmitted by turning on the turned-off other gate as well. By providing two gates, ejecting the charge generated by the dark current, and then transmitting the signal charge, the charge can be transmitted without mixture of the signal charge with the charge generated by the dark current. Accordingly, it is possible to realize an image sensor of a high-quality image with small noise.

The gate used to eject the dark current is formed in the contact and the gate is set to be in the ON state during a time other than the time of the transfer of the signal charge so that the dark current can be ejected. Thus, when the signal charge is transmitted, the state in which the dark current is ejected is realized. Therefore, the signal charge can be transmitted without mixture of the signal charge with the charge generated by the dark current. Accordingly, it is possible to realize an image sensor of a high-quality image with small noise.

In the above-described embodiments, the unit pixels have been exemplified. However, the embodiments of the present technology can be applied to a device or the like having a configuration in which a dark current occurs. In other words, the embodiments of the present technology can be applied to a portion in which a dark current occurs in a PN junction.

In the specification, the system refers to the entire device configured by a plurality of devices.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1)
An imaging element including:

a contact portion that connects first and second regions accumulating a charge to each other;

a first transfer portion that is formed between the first region and the contact portion; and

a second transfer portion that is formed between the second region and the contact portion.

(2)
The imaging element according to (1),

wherein the first region is a photoelectric conversion portion, and

wherein the second region is a charge retention portion that retains the charge accumulated in the photoelectric conversion portion.

(3)
The imaging element according to (1) or (2),

wherein a charge generated by a dark current is ejected by turning off the first transfer portion and turning on the second transfer portion before the charge accumulated in the first region is transmitted to the second region, and

wherein the charge accumulated in the first region is transmitted to the second region by turning on the first and second transfer portions after the ejection of the charge ends.

(4)
The imaging element according to any one of (1) to (3),

wherein a third transfer portion is connected to the contact portion, and

wherein a charge generated by a dark current is ejected by the third transfer portion during a period other than a period in which the charge accumulated in the first region is transmitted to the second region.

(5)
The imaging element according to any one of (1) to (3), wherein the first and second regions are formed over different substrates or over different materials.
(6)
The imaging element according to (1),

wherein the first region is a first charge retention portion that retains at least a part of the charge accumulated in a photoelectric conversion portion, and

wherein the second region is a second charge retention portion that retains the charge from the first charge retention portion.

(7)
The imaging element according to (1),

wherein the first region is a photoelectric conversion portion, and

wherein the second region is an output portion that outputs a charge accumulated in the photoelectric conversion portion to a signal line.

(8)
An imaging method of an imaging element including a contact portion that connects first and second regions accumulating a charge to each other, a first transfer portion that is formed between the first region and the contact portion, and a second transfer portion that is formed between the second region and the contact portion, the imaging method including:

ejecting a charge generated by a dark current by turning off the first transfer portion and turning on the second transfer portion before the charge accumulated in the first region is transmitted to the second region; and

transmitting the charge accumulated in the first region to the second region by turning on the first and second transfer portions after the ejection of the charge ends.

The present disclosure contains subject matter related to that disclosed in Japanese Priority Patent Application JP 2012-157071 filed in the Japan Patent Office on Jul. 13, 2012, the entire content of which is hereby incorporated by reference.

What is claimed is:

1. An imaging element comprising:
a contact portion that connects first and second regions accumulating a charge to each other;
a first transfer portion that is formed between the first region and the contact portion; and
a second transfer portion that is formed between the second region and the contact portion.

2. The imaging element according to claim 1,
wherein the first region is a photoelectric conversion portion, and
wherein the second region is a charge retention portion that retains the charge accumulated in the photoelectric conversion portion.

3. The imaging element according to claim 1,
wherein a charge generated by a dark current is ejected by turning off the first transfer portion and turning on the second transfer portion before the charge accumulated in the first region is transmitted to the second region, and
wherein the charge accumulated in the first region is transmitted to the second region by turning on the first and second transfer portions after the ejection of the charge ends.

4. The imaging element according to claim 1,
wherein a third transfer portion is connected to the contact portion, and
wherein a charge generated by a dark current is ejected by the third transfer portion during a period other than a period in which the charge accumulated in the first region is transmitted to the second region.

5. The imaging element according to claim 1, wherein the first and second regions are formed over different substrates or over different materials.

6. The imaging element according to claim 1,
wherein the first region is a first charge retention portion that retains at least a part of the charge accumulated in a photoelectric conversion portion, and
wherein the second region is a second charge retention portion that retains the charge from the first charge retention portion.

7. The imaging element according to claim 1,
wherein the first region is a photoelectric conversion portion, and
wherein the second region is an output portion that outputs a charge accumulated in the photoelectric conversion portion to a signal line.

8. An imaging method of an imaging element including a contact portion that connects first and second regions accumulating a charge to each other, a first transfer portion that is formed between the first region and the contact portion, and a second transfer portion that is formed between the second region and the contact portion, the imaging method comprising:
ejecting a charge generated by a dark current by turning off the first transfer portion and turning on the second transfer portion before the charge accumulated in the first region is transmitted to the second region; and
transmitting the charge accumulated in the first region to the second region by turning on the first and second transfer portions after the ejection of the charge ends.
